(19) United States
(12) Patent Application Publication
(10) Pub. No.: US 2005/0141651 A1
(43) Pub. Date: Jun. 30, 2005

(54) Method and system for modifying branch metric of Viterbi decoder for uncorrelated signals

(76) Inventors: Jiayi Zhuang, Shanghai (CN); Shengguan Hu, San Jose, CA (US); Jingdong Lin, Irvine, CA (US); Datong Chen, Fremont, CA (US)

Correspondence Address: PERKINS COIE LLP;PATENT-SEA, P.O. BOX 1247, SEATTLE, WA, 98111-1247, US

(21) Appl. No.: 10/867,273

(22) Filed: Jun. 14, 2004

Related U.S. Application Data
(60) Provisional application No. 60/533,193, filed on Dec. 30, 2003.

(51) Int. Cl. H04L 27/06; H03D 1/00

(52) U.S. Cl. 375/341; 714/796

(57) ABSTRACT

The present disclosure provides simple methods and systems for generating modified branch metrics for the Viterbi decoder so that the decoder can decode the uncorrelated incoming signals without the influence of either the signal power level or the noise variance. The proposed branch metrics noticeably improve the performance of the Viterbi algorithm in such cases. The present disclosure also provides methods and systems for reducing the length of the demodulated symbols for efficient computation. In an exemplary method, it is shown that the only requirement of the proposed modified branch metric, in addition to the traditional branch metric requirements, is the computation of the noise energy. In another exemplary system, an arrangement of circuit modules offers an implementation of one of the embodiments of the proposed method.

### REFERENCE TO RELATED APPLICATIONS

The present application claims the benefit of U.S. Provisional Application No. 60/533,193, filed 30 Dec. 2003 and entitled “Viterbi Decoder for Uncorrelated Signals,” the entirety of which is incorporated herein by reference.

### TECHNICAL FIELD

The present invention relates to a communication system and, more particularly, to a Viterbi decoder and its branch metrics.

### BACKGROUND

Typically a communication link includes three major elements: a transmitter, a communication channel, and a receiver. The transmitter and the receiver elements can be further subdivided into sub-systems, which include a data source, an encoder, a modulator, a demodulator, a decoder, and an original signal regenerator.

The data source generates the appropriate information signal that is intended to be sent to the destination. This signal may be digital or analog. Even for analog signals, it is often desirable to digitally encode the signal prior to its transmission. To provide error correction capacity at the receiver, the encoder transforms the information sequence into encoded sequence by adding redundancy to a digital data stream, in the form of additional data bits. The process of adding redundant information is known as “channel coding,” and the encoder is also known as “channel encoder.”

Coding is an effective method for trading bandwidth and implementation complexity against transmitter power. In general, higher transmitter power results in higher signal to noise ratio (SNR), which means the signal is less susceptible to noise and consequently to error at the receiving end. On the other hand, a low transmission power, and the resulting low SNR, can even make a signal unrecognizable and inseparable from the noise at the receiving end. Under such circumstances, where the probability of error is high, coding helps reduce the error probability and retrieve the original signal.

Different coding schemes are in use today, including Convolutional coding and Block coding. The Convolutional coding results in a serial data stream, whereas the Block coding results in large message blocks with a fixed number of elements within each block. The encoded signals in both methods include redundant information, as mentioned above. After encoding, the modulator converts the encoded information into physically transmittable signals. Modulation techniques depend on the type of information signal and the particular transmission medium.

A channel is the medium for transmission of the modulated information. It can be a copper wire, a coaxial cable, or the space. To various degrees, all channels introduce some form of distortion to the transmitted signal. The distortions introduced by different channels differ in their noise distribution. Some can be modeled as Additive White Gaussian Noise (AWGN), by which a noise with uniform power spectral density is assumed to be added to the information signal. Others introduce noise in bursts, include fading channels and multipath channels.

At the receiving end, the demodulator extracts the encoded information from the modulated signal. To retrieve the original digital signal, the extracted encoded data, which is also distorted to some degree by traveling through the channel, is subsequently decoded by the decoder. The decoding process is usually more complicated than the encoding process—it can also be computationally more intensive. Efficient decoding schemes have been developed over the years such as the Viterbi decoding algorithm for recovery of binary data. These schemes discover the distorted parts of the demodulated information and correct them. Finally, decoded data will be used to produce an estimate of the original signal.

The Viterbi algorithm is a self-correcting decoder that employs a maximum likelihood decoding rule. It computes some kind of probability measure for different “possible replacements” of the received data, based on the “actual” data received. Each possible string of data (up to the last received data symbol) is called a “data path,” and the probability measure associated with each data path is called a “cumulative metric.” Upon the arrival of a new data symbol, the algorithm adjusts each cumulative metric. This incremental adjustment is called a “branch metric.” In practice this is a series of add-compare-select operations. Ultimately, the Viterbi algorithm utilizes the cumulative metrics to calculate the maximum likelihood of a path being the best path. In other words, it finds the string of data most accurately representing the original encoded symbols.

Most of the existing codes perform relatively well under uniform channel error conditions, such as those of a Gaussian channel mentioned above, while the received data is correlated. However, to maximize the performance of the coding process, there is a need for improving the Viterbi algorithm for those channels in which the error tends to occur in bursts, such as fading channels, or when the received data is uncorrelated.

### BRIEF DESCRIPTION OF THE DRAWINGS

The foregoing aspects and many of the attendant advantages of the invention will become more readily appreciated as the same become better understood by reference to the following detailed description, when taken in conjunction with the accompanying drawings, wherein:

FIG. 1 is a functional block diagram of the transmitting part of a typical communication system, which transmits “data blocks.”

FIG. 2 is a schematic diagram of the performance of a fading channel, carrying bursts of data with a relatively short time lapse between them.

FIG. 3 is a schematic diagram of the performance of a fading channel, carrying bursts of data with a relatively long time lapse between them.

FIG. 4 is a functional block diagram of the receiving part of a typical communication system, which transmits “data blocks.”

FIG. 5 is a functional block diagram of an embodiment of the branch metric modification system, in accordance with the present invention.

FIG. 6 is the schematic representation of a bit fetching process in different bursts.

FIG. 7 is the flow diagram of the modified method of branch metric generation for the Viterbi algorithm according to one embodiment of this invention.

### DETAILED DESCRIPTION

The present invention relates to the modifications of the branch metrics of the Viterbi decoder so that the decoder can decode the uncorrelated incoming signals without the influence of either the signal power level or the noise variance. The proposed modifications noticeably improve the performance of the Viterbi algorithm in such cases. In the following description, several specific details are presented to provide a thorough understanding of the embodiments of the invention. One skilled in the relevant art will recognize, however, that the invention can be practiced without one or more of the specific details, or in combination with or with other components, etc. In other instances, well-known implementations or operations are not shown or described in detail to avoid obscuring aspects of various embodiments of the invention.

Reference throughout the specification to “one embodiment” or “an embodiment” means that a particular feature, structure, implementation, or characteristic described in connection with the embodiment is included in at least one embodiment of the present invention. Thus, the appearances of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

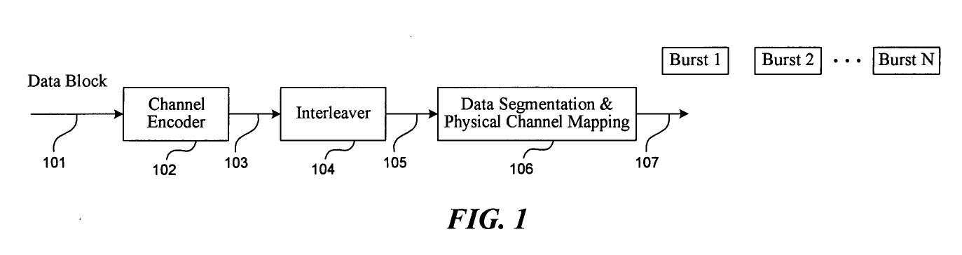

FIG. 1 is a functional block diagram of the transmitting part of a typical communication system, which transmits data blocks. A data block 101 represents data arriving in batches of specific size to be transmitted to some destination. Although a higher transmission power helps the signal to be more distinguished from the noise at the destination, or a higher bandwidth allows multiple copies of the same data to be transmitted in case some are distorted, both solutions are costly and can be avoided to a great extent by appropriate encoding of the data. Manipulation, alternative representation, and reordering of the data, along with the addition of redundancy, are some of the ways of protecting the data while optimizing the system. Accordingly, the data within the data blocks enter a channel encoder 102 to be coded and prepared for their transmission through the physical channel such that they would be recoverable at the destination, despite distortions due to noise and cochannel interference (interference).

An encoded data 103 enters an interleaver 104 for rearrangement of its content. This shuffling of the encoded data 103 helps avoid the loss of a sizable portion of the data in case of error bursts, which by definition are concentrated in time and are not distributed over the data. Once the damaged interleaved data is deinterleaved, the locally corrupted data is broken up and distributed over the entire deinterleaved data, creating independent errors and easier data correction.

It is important to note that the fading channels fit the model of a bursty error channel. The term fading is used when the amplitude of the received signal drastically varies as a result of the phase difference between a signal and its reflections. Such signals, at times, can weaken or practically cancel each other, or can combine to form a stronger signal. Although fading primarily is a result of the time variation of phases, the fading channel is an accurate model for channels susceptible to error bursts.

Interleaved data 105 is segmented to several “bursts” and mapped into physical channel bursts, 107, by a data segmentation and physical channel mapping module 106. But while data is being transmitted, the characteristics of the channel can change because of the physical changes in the structure of its medium. Channel characteristics influence the traveling signals and can uncorrelate two otherwise correlated data bursts. Changing weather conditions or other factors, for example, can change the “channel response,” which is defined as the response of a channel to an impulse-like signal, and which is an accurate representation of the channel characteristics.

In a typical communication system, the lengths of the bursts are chosen so that the channel response remains relatively constant during the transmission of each burst. If the time between two bursts is short enough, this assumption will stay valid even for two consecutive bursts, and preserves the correlation of the signals, of the noise, and of the interferences. However, if the time lapse between the two consecutive bursts is long enough, the signals, the noise, and the interference will be each uncorrelated and will adversely affect the performance of the traditional Viterbi channel decoder.

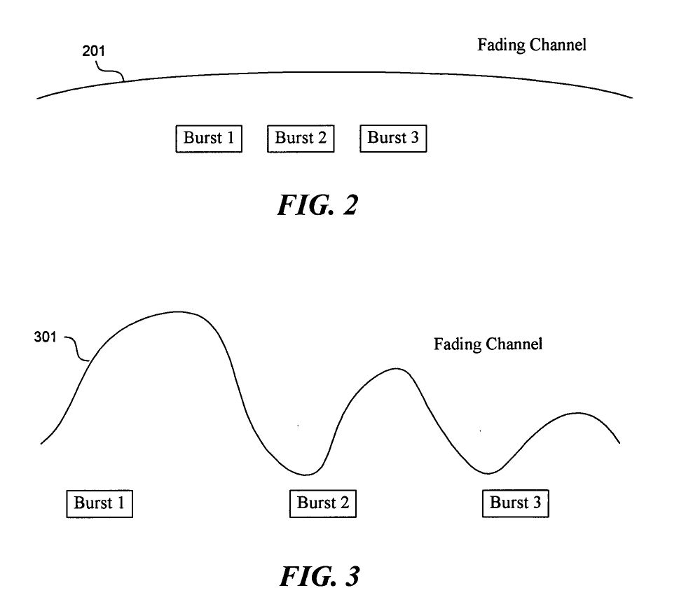

FIG. 2 is a schematic diagram of the performance of the traditional Viterbi algorithm if the time delay between transmitted bursts is short and the signals, the noise, and the interferences of the neighboring bursts are each correlated. In contrast, FIG. 3 schematically represents the performance of the traditional Viterbi algorithm when the time delay between transmitted bursts is long and consequently the signals, the noise, and the interferences affecting the signals of the neighboring bursts are each uncorrelated.

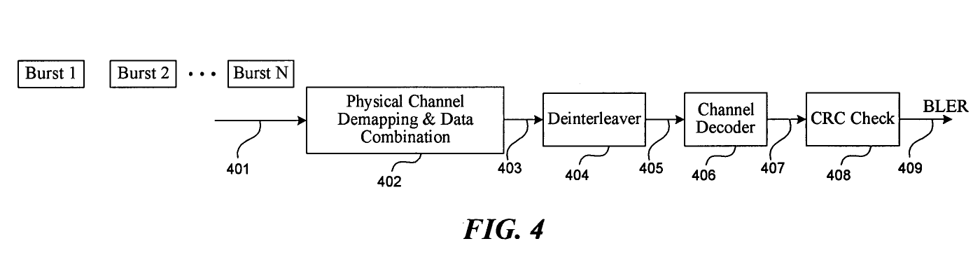

FIG. 4 is a functional block diagram of the receiving part of a typical communication system, which transmits data blocks. Received data bursts 401, in addition to the transmitted information signal, include noise and possibly interference. A physical channel demapping and data combination module 402 combines the received data bursts 401 into data blocks 403, which are still interleaved. Subsequently, a deinterleaver 404 rearranges the data block to its original encoded order.

If the time between transmitted physical channel bursts 107 has been long enough, the deinterleaver 404 will further distribute the data extracted from an already uncorrelated signal, noise, and interference. Such data, 405, entering a channel decoder 406, will affect the branch metrics of the Viterbi algorithm and will lower its performance. The modifications proposed in the present invention, among other advantages, will drastically improve the performance of the channel decoder 406 in such situations. A decoded block data 407 is finally checked by a Cyclic Redundancy Check (CRC) module 408 to identify most of the possible remaining errors.

In one embodiment the equations for the branch metric modifications are derived as follows. The aim of the Viterbi algorithm, as briefly mentioned above, is to find a set of {\hat{α}ₙ} that maximizes the likelihood function P({yₙ}|{αₙ}), where {αₙ} is the original signal before coding and {yₙ} is the quantized received signal, which consists of the coded signal and the noise. In other words, given our observations {yₙ}, the algorithm tries to find a set of data that maximizes the possibility of such observations. Ideally, the result of such a search should be the original data set {αₙ}, but, practically, {\hat{α}ₙ} will be the best result, considering the nondeterministic and random nature of the noise and the interferences. Here P({yₙ}|{αₙ}) represents the “cumulative metric” previously described, and if it can be written in the following form:
Jₙ=Jₙ₋₁+yₙ·s(αₙ) Eq. 1
then yₙ·s(αₙ) will represent the “branch metric,” since it incrementally adjusts the cumulative metric for each received symbol. The above likelihood function can be written as:

$$P ( \{ {y}_{n} \} \vert \{ {α}_{n} \} ) = {\prod }_{i = 1}^{n} \frac{1}{\sqrt{2 π {σ}^{2}}} \cdot exp ( - \frac{{( {y}_{i} - s ( {α}_{i} ) )}^{2}}{2 {σ}^{2}} ) \qquad Eq . 2$$

where {S(αₙ)} is the matched filter reconstruction of {αₙ} based on the received signals {yₙ}, and σ² is the variance of the assumed normally distributed (Gaussian) noise. As a result, {yₙ} and {S(αₙ)} have the same power density. After taking natural-log of both sides of Eq. 2, the following manipulations are possible:

$$\begin{matrix}{log}_{e} ( P ( \{ {y}_{n} \} \vert \{ {α}_{n} \} ) ) = - \frac{1}{2} {\sum }_{i = 1}^{n} {log}_{e} ( 2 π {σ}^{2} ) - {\sum }_{i = 1}^{n} \frac{{( {y}_{i} - s ( {α}_{i} ) )}^{2}}{2 {σ}^{2}} \\ = - \frac{1}{2} {\sum }_{i = 1}^{n} {log}_{e} ( 2 π {σ}^{2} ) - \\ {\sum }_{i = 1}^{n} \frac{{\vert {y}_{i} \vert}^{2} + {\vert s ( {α}_{i} ) \vert}^{2}}{2 {σ}^{2}} + {\sum }_{i = 1}^{n} \frac{{y}_{i} \cdot s ( {α}_{i} )}{{σ}^{2}} \\ = {log}_{e} ( P ( \{ {y}_{n - 1} \} \vert \{ {α}_{n - 1} \} ) ) - \frac{1}{2} {log}_{e} ( 2 π {σ}^{2} ) - \\ \frac{{\vert {y}_{n} \vert}^{2} + {\vert s ( {α}_{n} ) \vert}^{2}}{2 {σ}^{2}} + \frac{{y}_{n} \cdot s ( {α}_{n} )}{{σ}^{2}}\end{matrix} \qquad Eq . 3$$

If {yₙ} is stationary and correlated and noise has Gaussian distribution, the metric in Eq. 3 can be written in the form of Eq. 1, and, as mentioned above, yₙ·s(αₙ) will represent its branch metric. Note that in such a case the branch metric has no dependency on the noise variance. But, if {yₙ} is the concatenation of uncorrelated segments, such as in the case of data bursts with long delays between consecutive bursts, only the signal within each segment is stationary. Or there is a case in which the interference is stationary within each segment but uncorrelated between segments. Or yet another case in which both {yₙ} and interference are stationary within each segment but uncorrelated between segments. In such cases, Eq. 3 can be rewritten in the following form, while σₙ² represents noise variance at the n-th symbol:

$$\begin{matrix}{log}_{e} ( P ( \{ {y}_{n} \} \vert \{ {α}_{n} \} ) ) = - \frac{1}{2} {\sum }_{i = 1}^{n} {log}_{e} ( 2 π {σ}_{i}^{2} ) - {\sum }_{i = 1}^{n} \frac{{( {y}_{i} - s ( {α}_{i} ) )}^{2}}{2 {σ}_{i}^{2}} \\ = {log}_{e} ( P ( \{ {y}_{n - 1} \} \vert \{ {α}_{n - 1} \} ) ) - \\ \frac{1}{2} {log}_{e} ( 2 π {σ}_{n}^{2} ) - \frac{{\vert {y}_{n} \vert}^{2} + {\vert s ( {α}_{n} ) \vert}^{2}}{2 {σ}_{n}^{2}} + \\ \frac{{y}_{n} \cdot s ( {α}_{n} )}{{σ}_{n}^{2}}\end{matrix} \qquad Eq . 4$$

Since the value of

$$- \frac{1}{2} {log}_{e} ( 2 π {σ}_{n}^{2} ) - \frac{{\vert {y}_{n} \vert}^{2} + {\vert s ( {α}_{n} ) \vert}^{2}}{2 {σ}_{n}^{2}}$$

remains the same for all symbols and will merely add the same constant to the cumulative metrics of all paths, it can be dropped and Eq. 4 can be written in the following form:

$${J}_{n} = {J}_{n - 1} + \frac{{y}_{n} \cdot s ( {α}_{n} )}{{σ}_{n}^{2}} \qquad Eq . 5$$

Note that in this case, unlike the case in which {yₙ}was stationary and correlated, the branch metric part of Eq. 5 is a function of the Signal to Interference and Noise Ratio (SINRₙ). This is clearer when we write Eq. 5 in the following form:
Jₙ=Jₙ₋₁+sign(yₙ·s(αₙ))·SINRₙ Eq. 6
where sign(x)=1 for x>0 and −1 for x<0. As a matter of fact, in any situation in which the received signals are not uncorrelated symbol by symbol, Eq. 5 is a good approximation of the likelihood function.

To implement the latter set of equations, the present invention modifies Eq. 5 to the following equation: (Note that s(αₙ) will always be either +1 or −1, while {yₙ} is the soft output of the equalizer.)

$$\begin{matrix}{J}_{n} = {J}_{n - 1} + {w}_{n} \cdot {y}_{n} \cdot s ( {α}_{n} ) & Eq . 7 \\ where & \\ {w}_{n} = \frac{\sqrt{{E}_{s , n}}}{{σ}_{n}^{2}} & Eq . 8\end{matrix}$$

and where E_{s,n} is the total energy of the n-th received symbol.

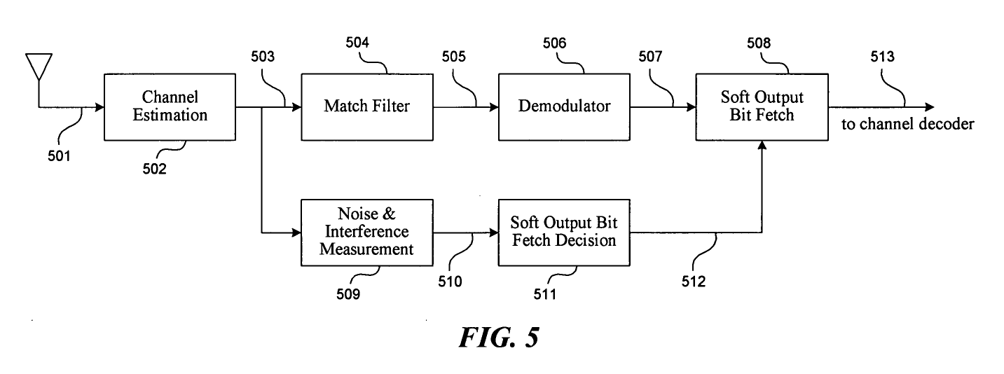

FIG. 5 is a functional block diagram of an embodiment of the branch metric modification system, in accordance with the present invention. This system, among other functions, generates the necessary values for the computation of the modified branch metrics of Eq. 7. Received signal bursts 501 first enter a channel estimator 502, which estimates the channel characteristics (channel response). The estimated channel parameters 503 help a matched filter 504 and a noise and interference measurement module 509 to more accurately perform their functions by having more information about what happened to the traveling signal as a result of the channel behavior. {S(αₙ)} is the sign of the correct encoded signals which have passed the channel and the processing at the receiving end before the channel decoder.

The output of the noise and interference measurement module 509 is utilized by a Soft Output Bit Fetch Decision module 511 to simplify required branch metric computations, as elaborated below. The noise and interference measurement module 509 also produces the estimated value of the energy of the noise per symbol, Eₙ, which will be proved to be the only required value for computing wₙ, or the only additional computation compared to the computation of a traditional branch metric. If the energy per symbol of information signal is Eₛ, the energy per symbol of information signal at the output of the matched filter 504 will be Eₛ². Now assuming that a demodulator 506 does not change the power ratio of the signal to the noise, wₙ can be written as:

$${w}_{n} = \frac{\sqrt{{E}_{s}^{2}}}{{E}_{s} \cdot {E}_{n}} = \frac{1}{{E}_{n}} \qquad Eq . 9$$

where Eₙ, as mentioned above, is produced by the noise and interference measurement module 509. Therefore, to compute wₙ, there is no need to estimate the energy of the signal. Also since Eₙ is estimated for each burst, wₙ is only updated once for each burst.

In yet another implementation, to simplify the process, wₙ is not multiplied by every yₙ output of a demodulator 506; rather, a procedure is introduced to select a limited number of its output bits. This procedure is called fetching. It should be noted that fetching is not required for the generation of modified branch metrics. It is merely an additional scheme to make decoder computations more efficient while using modified branch metrics.

In this procedure, if the soft output yₙ of the demodulator 506 has K bits, (b_{K-1}, b_{K-2}, . . . , b_{K}, . . . , b₀), only L bits of it will be fetched to form y′ₙ, (b_{i+L-1}, b_{i+L-2}, . . . , bᵢ₊₁, bᵢ). Here i is calculated by the Soft Output Bit Fetch Decision module 511, using the following equation:
i=round(log₂(wₙ))+c, 0≦i≦K−L
where c is a constant, computed based on the value range of yₙ and the bit margin. In fix point implementation, c is determined by the number of fix point bits of soft equalizer output (B1), the input number of fix point bits of Viterbi decoder (B2), and the range of round(log₂(wₙ)). c should satisfy
c+max(abs(round(log₂(wₙ))))+B2≧B1

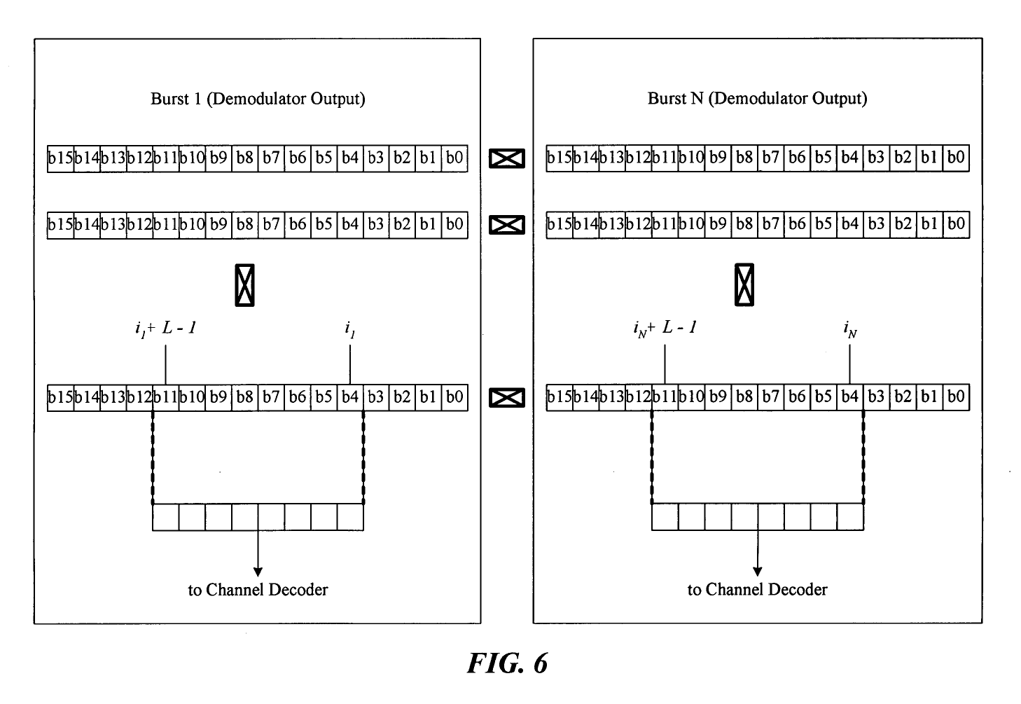

FIG. 6 is the schematic representation of a bit fetching process for the first and the rest of the bursts. The actual process of bit fetching is performed in a Soft Output Bit Fetching module 508. All the necessary components of Eq. 7, which include the components of the modified branch metric, are subsequently passed to the channel decoder, which in turn employs the Viterbi algorithm. y′ₙ is the simplified implementation of yₙ, which means not to divide wₙ, but to divide 2^{round(log}^{₂}^{(w}^{ₙ}⁾⁾. In the fix point implementation, it only needs to fetch the soft output of the equalizer from a certain bit i.

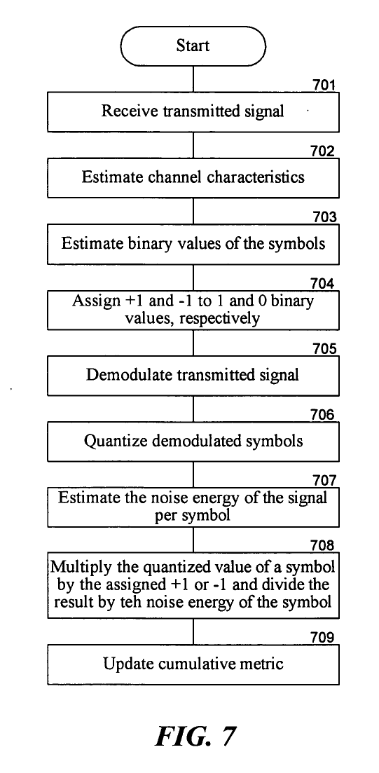

FIG. 7 is the flow diagram of the modified method of branch metric generation for the Viterbi algorithm according to an embodiments of this invention. At step 701 the transmitted signal, which carries the modulated and encoded data, is received. At step 702, using the received signal, the characteristics of the channel are estimated. The knowledge of channel characteristics will help to more accurately estimate and measure the signal and the noise during subsequent steps.

At step 703, the transmitted signal is demodulated and at step 704 the demodulated symbols are quantized to soft outputs. At step 705 the 0, or 1 binary values of the received signal is estimated and, subsequently at step 706, −1 or +1 is assigned to each binary value, respectively. At step 707 the noise is measured and the energy of the noise per data symbol is computed. At step 708 a branch metric is formed by multiplying the quantized value of a symbol by the assigned −1 or +1, and deviding by the noise energy of the same symbol. In step 709 this branch metric is used to update the cumulative metric.

The preferred and several alternate embodiments have thus been described. One of ordinary skill after reading the foregoing specification will be able to effect various changes, alterations, combinations, and substitutions of equivalents without departing from the broad concepts disclosed. It is therefore intended that the scope of the letters patent granted hereon be limited only by the definitions contained in the appended claims and equivalents thereof, and not by limitations of the embodiments described herein.

1. A method of generating branch metrics for a Viterbi algorithm used for decoding transmitted encoded symbols, the method comprising:
receiving a transmitted signal;
demodulating and quantizing the symbols of the received signal;
estimating the binary values of the symbols of the received signal;
assigning a +1 to the estimated binary value 1, and a −1 to the estimated binary value 0;
estimating the noise energy of the signal per received symbol; and
computing a branch metric that is directly proportional to the quantized value of the symbol and to the assigned value of the symbol and inversely proportional to the noise energy of the symbol.

2. The method of claim 1, wherein the transmission is wireless.

3. The method of claim 1, wherein the transmission medium is the space.

4. The method of claim 1, wherein the symbols are binary.

5. The method of claim 1, wherein the quantization produces hard-decision output.

6. The method of claim 1, wherein the quantization produces soft-decision output.

7. The method of claim 1, wherein the transmission is in bursts.

8. The method of claim 1, wherein the encoded data is interleaved.

9. The method of claim 1, wherein the binary value estimator is a matched filter.

10. The method of claim 1, wherein the noise energy is estimated once for an entire burst.

11. The method of claim 1, wherein only some bits of a quantized symbol are chosen to represent its value.

12. The method of claim 1, wherein only some bits of a quantized symbol are chosen to represent its value in accordance with the value range of the quantized symbol and the bit margin.

13. The method of claim 1, wherein only some bits of a quantized symbol are chosen to represent its value using an equation of the form
i=round(log₂(wₙ))+c, 0≦i≦K−L.

14. A method of generating branch metrics for a Viterbi algorithm used for decoding transmitted bursts of data symbols, the method comprising:
receiving a transmitted signal;
demodulating and quantizing the symbols of the received signal;
estimating the binary values of the symbols of the received signal;
assigning a +1 to the estimated binary value 1, and a −1 to the estimated binary value 0;
estimating the noise energy of the signal per received symbol; and
computing a branch metric that is directly proportional to the quantized value of the symbol and to the assigned value of the symbol and inversely proportional to the noise energy of the symbol.

15. The method of claim 14, wherein the bursts are uncorrelated.

16. The method of claim 14, wherein the bursts are segments of data blocks.

17. The method of claim 14, wherein the transmission is wireless.

18. The method of claim 14, wherein the transmission medium is the space.

19. The method of claim 14, wherein the symbols are binary.

20. The method of claim 14, wherein the quantization produces hard-decision output.

21. The method of claim 14, wherein the quantization produces soft-decision output.

22. The method of claim 14, wherein the encoded data is interleaved.

23. The method of claim 14, wherein the binary value estimator is a matched filter.

24. The method of claim 14, wherein the noise energy is estimated once for an entire burst.

25. The method of claim 14, wherein only some bits of a quantized symbol are chosen to represent its value.

26. The method of claim 14, wherein only some bits of a quantized symbol are chosen to represent its value in accordance with the value range of the quantized symbol and the bit margin.

27. The method of claim 14, wherein only some bits of a quantized symbol are chosen to represent its value using an equation of the form
i=round(log₂(wₙ))+c, 0≦i≦K−L.

28. A system for generating branch metrics for a Viterbi algorithm used for decoding transmitted bursts of data symbols, the system comprising:
a channel estimator;
a matched filter, which assigns a +1 to the estimated binary value 1, and a −1 to the estimated binary value 0;
a demodulator, with soft output capability;
a decoder using the Viterbi algorithm;
a noise and interference measurement module, which also computes the noise energy; and
an arrangement in which:
the channel estimator receives the transmitted signal;
the matched filter receives the transmitted signal and receives the channel information from the channel estimator;
the noise and interference measurement module receives the transmitted signal and receives the channel information from the channel estimator;
the demodulator receives the transmitted signal and receives the assigned values to the binary estimates of the data symbols from the matched filter; and
the decoder receives the matched filter, the demodulator, and the noise and interference measurement module outputs.

29. A system for generating branch metrics for a Viterbi algorithm used for decoding transmitted bursts of data symbols, the system comprising:
a channel estimator;
a matched filter, which assigns a +1 to the estimated binary value 1, and a −1 to the estimated binary value 0;
a demodulator, with soft output capability;
a decoder using the Viterbi algorithm;
a noise and interference measurement module, which also computes the noise energy;
a soft output bit-fetch decision making module capable of computing the number of bits to be fetched from the output of the demodulator;
a soft output bit fetcher module capable of fetching a specified number of bits from the output of the demodulator; and
an arrangement in which:
the channel estimator receives the transmitted signal;
the matched filter receives the transmitted signal and receives the channel information from the channel estimator;
the noise and interference measurement module receives the transmitted signal and receives the channel information from the channel estimator;
the demodulator receives the transmitted signal and receives the assigned values to the binary estimates of the data symbols from the matched filter;
the soft output bit fetch decision making module receives the noise and interference information from the noise and interference measurement module;
the soft output bit fetcher module receives information from the soft output bit-fetch decision making module and the demodulator; and
the decoder receives the matched filter, the soft output bit fetcher module, and the noise and interference measurement module outputs.
